(19) United States
(12) Patent Application Publication
(10) Pub. No.: US 2007/0013075 A1
(43) Pub. Date: Jan. 18, 2007

(54) MODULAR CONTAINMENT STRUCTURE

(76) Inventors: Andreas Froese, Barrhead, AB (CA); Anatoli Froese, Barrhead, AB (CA)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(21) Appl. No.: 11/427,169

(22) Filed: Jun. 28, 2006

(30) Foreign Application Priority Data
Jun. 28, 2005 (CA) 2,511,355

(51) Int. Cl. H01L 23/52

(52) U.S. Cl. 257/758

(57) ABSTRACT

A modular containment system which has a plurality of stackable building elements, including two or more peripheral sidewall members, a roof and a base. Means are provided for coupling each of the building elements to an adjoining building element. The building elements are stacked such that the two or more peripheral sidewall members are stacked on top of the base and the roof is stacked on top of the two or more sidewall members.

### FIELD OF THE INVENTION

The present invention relates to a modular containment structure.

### BACKGROUND OF THE INVENTION

Containment structures such as grain bins are used to store grain after it has been harvested. Grain bins are fabricated from galvanized steel. Grains bin fabricated from galvanized steel are expensive and are not strong enough to contain heavier materials such as fertilizer. Once built, they are difficult to modify or disassemble. It can also be difficult to modify the size or height of the bin once it has been fabricated. Additionally, many galvanized steel bins have wooden floors which require replacing after a period of use. Furthermore, grain bins can be susceptible to tipping in strong winds, particularly where the grain bin does not contain enough grain material to weight it down, or where the tie down anchors have not been used.

### SUMMARY OF THE INVENTION

What is required is a portable containment system that can be used as a grain bin.

According to the present invention there is provided a modular containment system which has a plurality of stackable building elements, including two or more peripheral sidewall members, a roof and a base which functions as the bottom. Means are provided for coupling each of the building elements to an adjoining building element. The building elements are stacked such that the two or more peripheral sidewall members are stacked on top of the base and the roof is stacked on top of the two or more sidewall members.

### BRIEF DESCRIPTION OF THE DRAWINGS

These and other features of the invention will become more apparent from the following description in which reference is made to the appended drawings, the drawings are for the purpose of illustration only and are not intended to in any way limit the scope of the invention to the particular embodiment or embodiments shown, wherein:

FIG. 1 is a side elevation view, of a modular containment structure;

FIG. 2 is a side elevation view, in section, of a modular containment structure illustrated in FIG. 1;

FIG. 3 is an exploded side elevation view of the modular containment structure illustrated in FIG. 1;

FIG. 4 is a top plan view of a unitary peripheral sidewall member;

FIG. 5 is a top plan view of a peripheral sidewall member fabricated in sections and secured together;

FIG. 6 is a side elevation view, in section, of a modular containment structure illustrated in FIG. 1, with a hopper;

FIG. 7 is a side elevation view of the hopper illustrated in FIG. 6.

### DETAILED DESCRIPTION OF THE PREFERRED EMBODIMENT

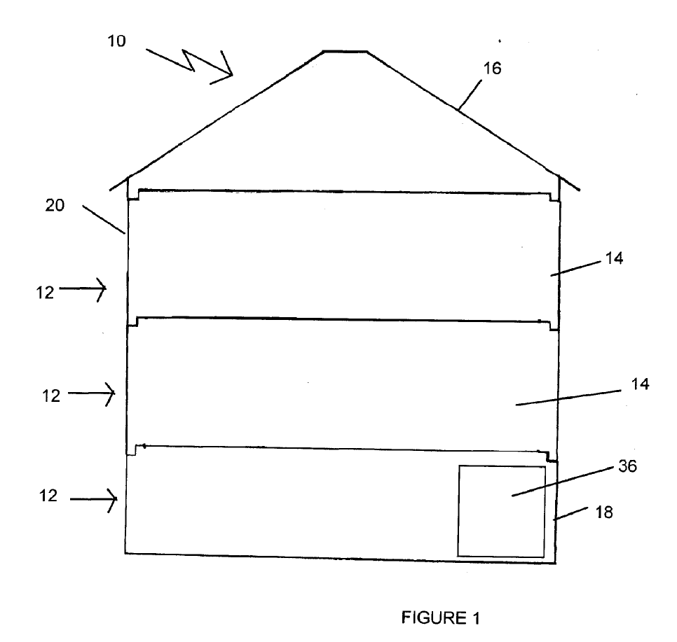

The preferred embodiment, a modular containment structure generally identified by reference numeral 10, will now be described with reference to FIGS. 1 through 7.

Structure and Relationship of Parts:

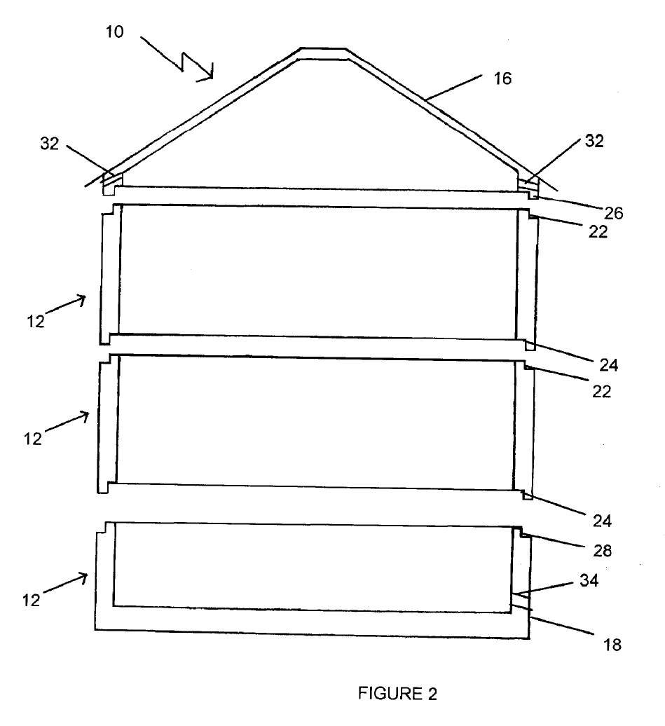

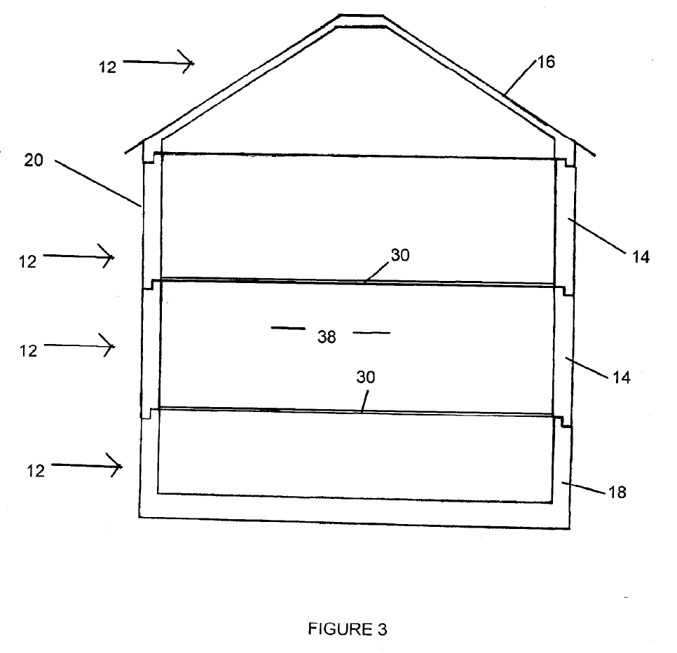

Referring to FIG. 1, there is illustrated a modular containment system generally reference by numeral 10. Referring to FIG. 2, modular containment 25 system 10 includes a plurality of stackable building elements 12, which can include two or more peripheral sidewall members 14, a roof 16 and a base 18 which operates as the bottom. Referring to FIG. 3, building elements 12 are stacked such that two peripheral sidewall members 14 are stacked on top of base 18. Roof 16 is stacked on top of the top peripheral sidewall member 14 so as to form a storage container 20.

Referring to FIG. 2, each peripheral sidewall member 14 has a top edge profile 22 and a base edge profile 24. Top edge profile 22 is adapted to engage with base edge profile 24 of an adjoining peripheral side wall member 14. Roof 16 has a base edge profile 26 adapted to engage top edge profile 22 of adjoining peripheral sidewall member 14. Base 18 has a top edge profile 28 adapted to engage base edge profile 24 of lowest peripheral sidewall member 14. A seal 30 is provided between each of stackable building elements 12.

In the illustrated embodiment, each of the stackable building elements 12 is fabricated from concrete with reinforced with rebar to give the structure strength so that can hold grain, or heavier materials such as fertilizer, salt or sand. It will be appreciated that other materials than just concrete can also be used to fabricate building elements 12 or that one or more of the building elements 12 could also be fabricated from materials other than concrete or include other materials in addition to concrete in their fabrication

Referring to FIG. 2, roof 16 is provided with aeration apertures 32. Base 18 is also provided with aeration apertures 34. Referring to FIG. 1, peripheral sidewall members 14 can have closable openings 36 allowing for access to or from an interior 38 of container 20 illustrated in FIG. 3.

Operation:

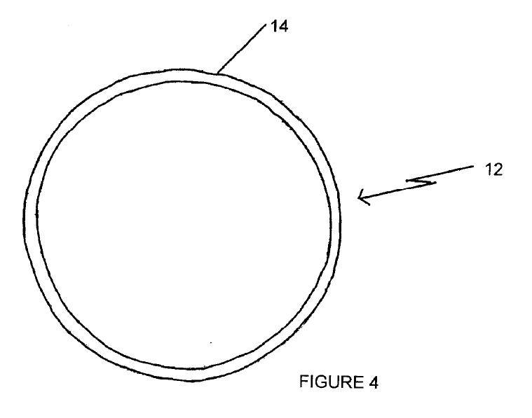

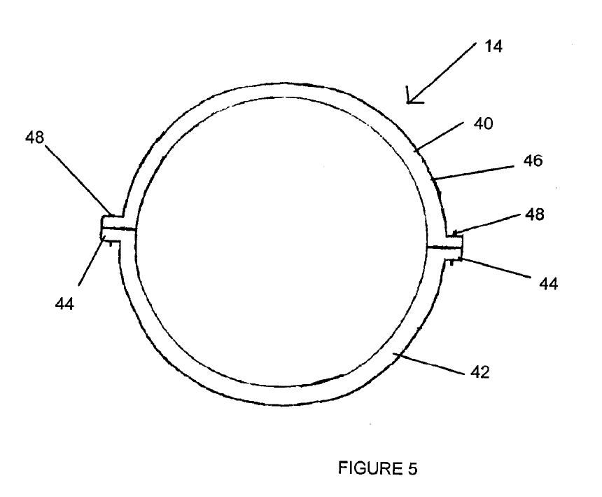

The use and operation of modular containment system generally identified by reference numeral 10 will now be described with reference to FIGS. 1 through 7. Referring to FIG. 2, building elements 12 can be pre-fabricated out of concrete. Building elements 12 can be strengthened with rebar during the prefabrication process. Building elements 12 are then transferred to a site where containment system 10 is to be erected. Referring to FIG. 3, building members 12 are then stacked such that one of peripheral sidewall members 14 is stacked on top of base 18 which operates as the bottom or floor. Additional peripheral sidewall members 14 are then added as desired. Finally, roof 16 is stacked on top last peripheral sidewall members 14 so as to form container 20. During the stacking process, seals 30 are placed between building elements 12. It will be appreciated that while the building elements 12 are preferred to be made of concrete, one or more of the building elements 12 could also be fabricated from materials other than concrete or include other materials in addition to concrete in their fabrication. Referring to FIG. 4, peripheral sidewalls can be of a unitary construction for ease of fabrication. Referring to FIG. 5, where peripheral sidewalls of a larger circumference are required, such as those over 19 feet, peripheral sidewalls 14 can be constructed in several sections and then assembled together. By way of example, a first halve 40 and a second halve 42 can be fabricated with flanges 44 on exterior surface 46. Flanges 44 are then aligned and coupling such as a pin 48 is inserted through flanges 44 to secure first halve 40 to second halve 42. It will be appreciated that other methods of securing first halve 40 and second halve 42 can be used. It will also be appreciate that there could be more than two sections.

Referring to FIG. 1, when fabricated from concrete, storage container 20 is less likely to tip in high winds due to the weight of the concrete even when it is empty. It is extremely durable yet inexpensive to fabricate. It can be transported and assembled easily. It can also be easily disassembled and transported to another site. Storage container 20 can be customized depending on the height desired. In the illustrated embodiment 10, only two peripheral sidewalls 14 are shown, however it will be appreciated that more than two can be used to increase the height of storage container 20. In the illustrated embodiment, peripheral sidewalls 14 are circumferentially round, however the peripheral sidewalls could be prefabricated in other circumferential shapes.

After being erected, storage container 20 can be use to store grain or other materials such as fertilizer, salt or sand. When necessary, storage container 20 can easily be disassembled and move to another site. Even base 18 can be moved easily as it is prefabricated rather than being poured onsite.

Variations

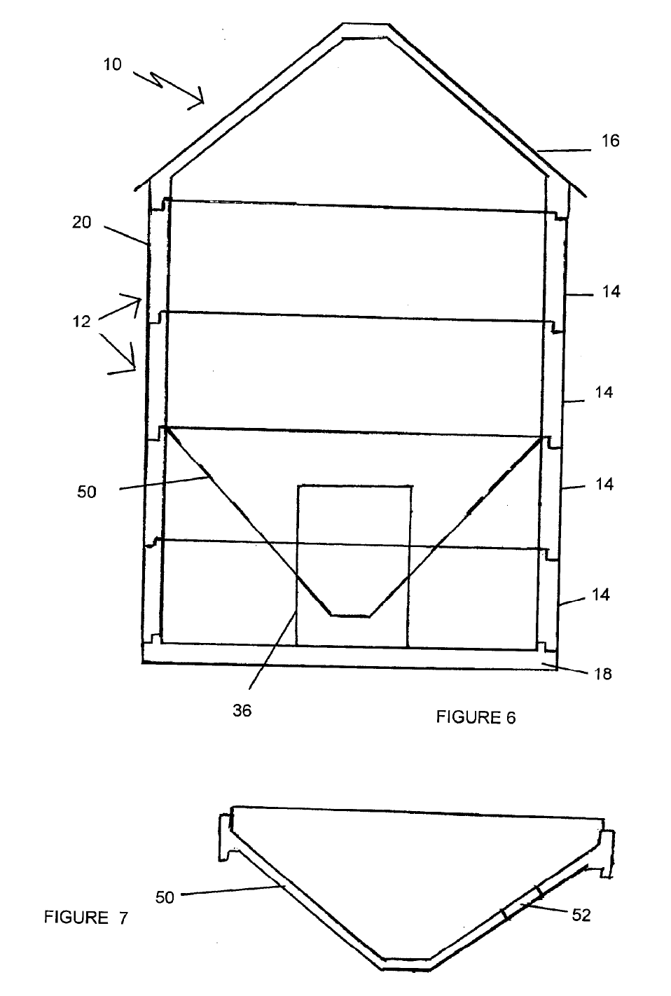

Referring to FIG. 6, storage container 20 can be fitted with a hopper 50 illustrated in FIG. 7. Hopper 50 is particularly useful when storage container 20 is used to contain grain. Hopper 50 can also have an opening 52 for an aeration system or to provide access.

Cautionary Warnings:

In this patent document, the word “comprising” is used in its non-limiting sense to mean that items following the word are included, but items not specifically mentioned are not excluded. A reference to an element by the indefinite article “a” does not exclude the possibility that more than one of the element is present, unless the context clearly requires that there be one and only one of the elements.

It will be apparent to one skilled in the art that modifications may be made to the illustrated embodiment without departing from the spirit and scope of the invention as hereinafter defined in thc Claims.

1. A modular containment system, comprising;
a plurality of stackable building elements, including two or more peripheral sidewall members, a roof and a base;
the building elements being stacked such that the two or more peripheral sidewall members are stacked on top of the base; and the roof is stacked on top of the two or more sidewall members; and
means for coupling each of the building elements to an adjoining building element.

2. The apparatus described in claim 1, wherein the means for coupling each of the building elements to an adjoining building element includes the two or more peripheral sidewall members each having a top edge profile and a base edge profile, the top edge profile being adapted to engage with the base edge profile of an adjoining peripheral side wall member, the roof having a base edge profile adapted to engage the top edge profile of one of the two or more peripheral sidewall members; and the base having a top edge profile adapted to engage the base edge profile.

3. The apparatus described in claim 1, wherein seal is provided between each stackable building elements.

4. The apparatus as described in claim 1, wherein one or more of the building elements are prefabricated from concrete.

5. The apparatus as described in claim 4, wherein each of the stackable building elements is reinforced with rebar.

6. The apparatus as described in claim 1, wherein the roof is provided with aeration apertures.

7. The apparatus as described in claim 1, wherein the base is provided with aeration apertures.

8. The apparatus as described in claim 1, wherein at least one of the two or more peripheral sidewall members has an opening for access to an interior.

9. The apparatus as described in claim 1, wherein each of the two or more peripheral sidewall members are fabricated in sections and then secured together.

10. A method of fabricating a modular containment system, comprising the following steps;
firstly, providing a plurality of stackable building elements, including two or more peripheral sidewall members, a roof and a base, and means for coupling each of the stackable building elements to an adjoining stackable building element;
secondly, stacking the two or more peripheral sidewall members on top of the base; and
thirdly, stacking the roof on top of the two or more sidewall members.

11. The method described in claim 10, wherein the means for coupling each of the building elements to an adjoining building element includes the two or more peripheral sidewall members each having a top edge profile and a base edge profile, the top edge profile being adapted to engage with the base edge profile of an adjoining peripheral side wall member, the roof having a base edge profile adapted to engage the top edge profile of one of the two or more peripheral sidewall members; and the base having a top edge profile adapted to engage the base edge profile.

12. The method as described in claim 10 , wherein a seal is provided between each stackable building elements.

13. The method as described in claim 10, wherein each of the stackable building elements is pre-fabricated from concrete

14. The method as described in claim 13, wherein each of the stackable building elements is reinforced with rebar.

15. The method as described in claim 10, wherein the roof is provided with aeration apertures.

16. The method as described in claim 10, wherein the base is provided with aeration apertures.

17. The method as described in claim 10, wherein at least one of the two or more peripheral sidewall members has an opening for access to an interior.

18. The method as described in claim 10, wherein each of the two or more peripheral sidewall members are fabricated in sections and then secured together.
